(19) United States
(12) Patent Application Publication
(10) Pub. No.: US 2011/0298005 A1
(43) Pub. Date: Dec. 8, 2011

(54) METHOD FOR FABRICATING AN N-TYPE SEMICONDUCTOR MATERIAL USING SILANE AS A PRECURSOR

(75) Inventors: Fengyi Jiang, Jiangxi (CN); Li Wang, Jiangxi (CN); Chunlan Mo, Jiangxi (CN); Wenqing Fang, Jiangxi (CN)

(73) Assignee: LATTICE POWER (JIANGXI) CORPORATION, Nanchang, Jiang Xi (CN)

(21) Appl. No.: 12/680,261

(22) PCT Filed: Oct. 12, 2007
(86) PCT No.: PCT/CN07/02946

§ 371 Date: Aug. 8, 2011

(30) Foreign Application Priority Data
Oct. 12, 2007 (CN) PCT/CN2007/002946

(51) Int. Cl. H01L 33/02; H01L 21/20

(52) U.S. Cl. 257/103; 438/478; 257/E21.09; 257/E33.023

(57) ABSTRACT

A method for fabricating a group III-V n-type nitride structure comprises fabricating a growth Si substrate and then depositing a group III-V n-type layer above the Si substrate using silane gas (SiH₄) as a precursor at a flow rate set to a first predetermined value (210). Subsequently, the SiH₄ flow rate is reduced to a second predetermined value during the fabrication of the n-type layer (220). The method also comprises forming a multi-quantum-well active region above the n-type layer. In addition, the flow rate is reduced over a predetermined period of time, and the second predetermined value is reached at a predetermined, sufficiently small distance from the interface between the n-type layer and the active region (230).

### BACKGROUND

1. Field of the Invention

The present invention relates to the design of semiconductor light-emitting devices. More specifically, the present invention relates to a technique for epitaxially fabricating an n-type nitride semiconductor material with high-quality crystalline and electrical properties and a method for fabricating semiconductor light-emitting devices using such n-type nitride semiconductor material which exhibits high luminance efficiency and reliability.

2. Related Art

Compared with traditional lighting technologies, light emitting diodes (LED) have many advantages including less electrical power consumption, higher efficiency, a longer life span, and better performance. In addition, LEDs are less affected by shock, vibration, and temperature variation. As a result, LED technology has been employed in a wide variety of applications, such as video display, mobile electronic products, and point light sources. Researches in the fabrication of LED devices have demonstrated that Group III-V nitride compounds (e.g., GaN, InN, and AlN) and alloys (e.g., AlGaN, InGaN, and AlGAlnN) can generate efficient luminescence.

One crucial element in the fabrication of a light-emitting device is the design and quality of the active region in a light-emitting device. When p-type and n-type semiconductor materials are interfaced with each other, the junction exhibits a property different from that of either type of material alone. More specifically, when forward-bias is applied to the P-N interface region, the carriers (i.e., holes from the p-type layer and electrons from the n-type layer) recombine in the active region and thus energy is released in the form of photons. Typically, the active region is formed by a multi-quantum-well (MQW) structure between the p-type layer and the n-type layer, and it facilitates higher carrier density and hence an increased recombining rate of the carriers. The faster the carriers recombine, the more efficient a light-emitting device becomes.

It is generally desirable to have LEDs that exhibit a small turn-on voltage. When an LED is reverse biased, on the other hand, it is preferred to have the highest possible reverse breakdown voltage so as to increase the reliability of the LED.

### SUMMARY

One embodiment of the present invention provides a method for fabricating a group III-V n-type nitride structure. The method includes fabricating a growth Si substrate and then depositing a group III-V n-type layer above the Si substrate using silane gas (SiH4) as a precursor at a flow rate set to a first predetermined value corresponding to a first carrier density. Subsequently, the SiH4 flow rate is reduced to a second predetermined value corresponding to a second carrier density during the fabrication of the n-type layer, wherein the second carrier density is less than the first carrier density. The method also comprises forming a multi-quantum-well active region above the n-type layer. In addition, the flow rate is reduced over a predetermined period of time, and the second predetermined value is reached at a predetermined, sufficiently small distance from the interface between the n-type layer and the active region.

In a variation of this embodiment, the second carrier density is approximately one-tenth of the first carrier density.

In a further variation, the first predetermined value is approximately carrier density is approximately 1×1018 cm-3 to 1×1019 cm-3.

In a further variation, the second carrier density is approximately 2×1017 cm-3 and 8×1017 cm-3.

In a variation of this embodiment, the predetermined period of time is approximately 1,000 seconds.

In a variation of this embodiment, the flow rate is reduced linearly based on a substantially constant reduction speed or non-linearly based on a varying reduction speed.

In a variation of this embodiment, the predetermined distance is less than or equal to 1,000 angstroms.

In a variation of this embodiment, the predetermined distance is greater than or equal to 100 angstroms.

### BRIEF DESCRIPTION OF THE FIGURES

The drawings accompanying and forming part of this specification are included to depict certain aspects of the invention. The invention may be better understood by reference to one or more of these drawings in combination with the description presented herein. It should be noted that the features illustrated in the drawings are not necessarily drawn to scale.

FIG. 1 illustrates an LED based on nitride semiconductor materials manufactured using a metalorganic chemical vapor deposition (MOCVD) method.

FIG. 2 presents a flowchart illustrating the process of fabricating an n-type layer by reducing the SiH4 flow rate in accordance with one embodiment of the present invention.

FIG. 3 illustrates an exemplary embodiment of an LED with an n-type layer manufactured in accordance with the method disclosed in the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the scope of the present invention. Thus, the present invention is not limited to the embodiments shown, but is to be accorded the widest scope consistent with the claims.

### Overview

During the process of depositing the n-type layer in a GaN-based LED, ammonia gas (NH3) or silane (SiH4) is often used as a precursor for the donor material. While both NH3 and SiH4 facilitate the creation of an LED structure with a high reverse breakdown voltage and good emission efficiency, an n-type layer fabricated with SiH4 has a better crystalline structure and is therefore more reliable. On the other hand, when NH3 is used as a nitrogen source precursor, the reverse breakdown voltage can be increased by gradually reducing the NH3 flow rate during the epitaxial growth of the n-type layer, while small turn-on voltage of the LED can still be maintained.

Embodiments of the present invention provide a method for fabricating a high-quality n-type nitride semiconductor material by using silane (SiH4) as a precursor and gradually reducing the SiH4 flow rate to the extent that the final flow rate is significantly smaller than the initial flow rate.

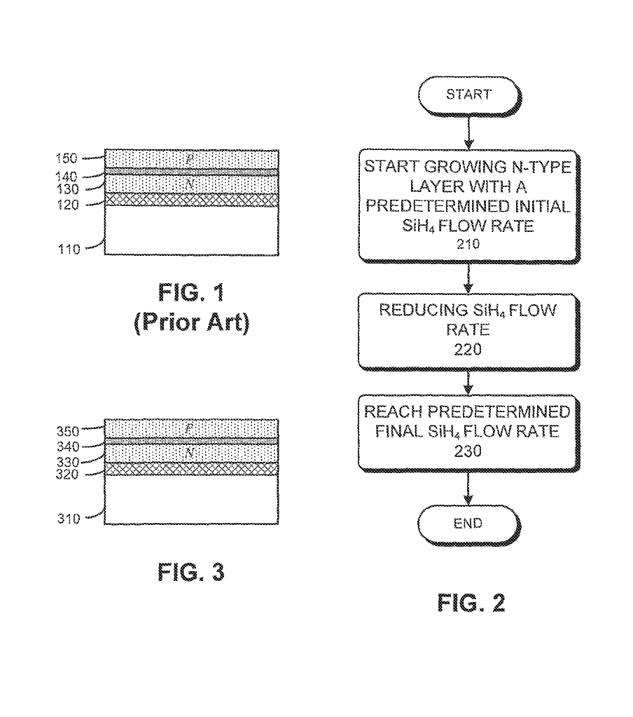

FIG. 1 illustrates an LED based on nitride semiconductor materials manufactured using an MOCVD method. In one exemplary fabrication process, a group III-V nitride layered structure of an LED is first fabricated on a growth Si substrate 110. Low temperature deposition enables use of various substrates, including silicon, sapphire, and silicon carbide.

Optionally, a buffer layer 120 can be grown on substrate 110 prior to fabricating an n-type layer 130. This layer is grown for purposes of lattice-constant and/or thermal-expansion coefficient matching. After n-type layer 130 is grown on buffer layer 120, an active region 140 and a group III-V p-type nitride layer 150 are formed separately above n-type layer 130.

In one embodiment, active region 140 comprises an InGaN/GaN multi-quantum-well (MQW) structure, which facilitates achieving a higher carrier density. A higher carrier density results in an increased recombination rate of the carriers, which in turn improves light-emitting efficiency.

The epitaxial growth of n-type layer 130 can use both a gallium (Ga) source precursor (e.g., Trimethylgallium gas) and a silicon (Si) source precursor (SiH4 gas), which are typically introduced into the deposition chamber at a predetermined, constant flow rate during the deposition process. Not shown in FIG. 1 are a pair of positive and negative electrodes placed on the p-type and n-type layers, respectively. These electrodes can be manufactured using any conventional electrode fabrication technique.

FIG. 2 presents a flowchart illustrating the process of fabricating an n-type layer by reducing the SiH4 flow rate in accordance with one embodiment of the present invention. The fabrication process starts with depositing an n-type layer above a buffer layer of a group III-V nitride-based LED at an initial SiH4 flow rate (operation 210). In one embodiment, the initial flow rate is a normal flow rate for epitaxial growth of an n-type layer. Such normal flow rate can correspond to an n-type carrier density of approximately 5×1018 cm-3. Note that the actual value of the flow rate may vary from system to system, depending on for example the size of the growth chamber.

Once the n-type deposition is in progress, the SiH4 flow rate is reduced by increments until it reaches a predetermined final flow rate (operation 220). In one embodiment, the initial SiH4 flow rate begins to decrease shortly after epitaxial growth starts. In a further embodiment, the initial SiH4 flow rate does not begin to decrease until the epitaxial growth at the initial flow rate has been maintained for a predetermined period of time. In either case, the final flow rate is significantly lower than the initial flow rate. In one embodiment, the final flow rate is between 7.5% and 15% of the initial flow rate. For example, if the initial flow rate corresponds to an n-type carrier density of 5×1018 cm-3, the final flow rate can correspond to an n-type carrier density of approximately 3.75×1017 cm-3 to 7.5×1017 cm-3.

There are a number of approaches to gradually reduce the SiH4 flow rate from the initial flow rate to the final flow rate. For example, a linear reduction with a constant reduction speed can be used. Alternatively, the reduction can be based on a nonlinear function, such as a parabolic curve with a varying reduction speed. The common feature of these various approaches is that the flow rate is reduced consistently, and this feature ensures a small turn-on voltage for the LED. Because of the steady reduction of the SiH4 flow rate and the significant difference between the initial and final flow rates, ideally, the duration of the flow rate reduction is sufficiently long. In one embodiment, the duration of this flow-rate reduction process is approximately 1,000 seconds.

The final flow rate is reached when the flow rate reduction terminates at a given, sufficiently small distance from the interface between the n-type layer and the active region (operation 230). The final flow rate is maintained for a significantly shorter period of time until the completion of fabricating the n-type layer. In one embodiment, the distance between the interface and the location in the n-type layer where the final flow rate is reached ranges between 100 and 1,000 angstroms

FIG. 3 illustrates an exemplary embodiment of an LED with an n-type layer manufactured in accordance with the method disclosed in the present invention. With a metalorganic chemical vapor deposition (MOCVD) method, a group III-V nitride layered structure of an LED is first fabricated on a growth Si substrate 310. A buffer layer 320 is grown on substrate 310. Note that other substrate materials, such as SiC and sapphire, can also be used. Subsequently, an n-type layer 330 with a thickness of approximately 1 micrometer is grown on buffer layer 320, while SiH4 is used as a precursor. In the beginning of the deposition of n-type layer 330, the initial SiH4 flow rate corresponds to a carrier density of approximately 5×1018 cm-3. During the deposition, the flow rate is linearly reduced, so that the carrier density after the flow rate reaches its final value is approximately 5×1017 cm-3. Generally, the initial silane flow rate can correspond to a carrier density between 1×1018 cm-3 and 1×1019 cm-3. The final silane flow rate can correspond to a carrier density between 2×1017 cm-3 and 8×1017 cm-3. The duration of the flow rate reduction—from the initial flow rate to the final flow rate—can be approximately 1,000 seconds.

The process of SiH4 flow rate reduction terminates when the final flow rate is reached. In one embodiment, the area in n-type layer 330 where the final flow rate is reached is about 100 angstroms away from the interface between n-type layer 330 and an active region 340, which comprises a MQW structure. In addition, a p-type layer 350 is formed on n-type layer 330. Although not shown in FIG. 3, an n-type electrode and a p-type electrode can be electrically coupled to n-type layer 330 and p-type layer 350.

An LED fabricated according to the method described above can exhibit a turn-on voltage of approximately 3V and a breakdown voltage of approximately 40V. In addition, the LED exhibits high emission efficiency and excellent reliability.

The invention is illustrated with different embodiments, described in detail, and with examples for purposes of facilitating the implementation of the different features or components of the invention. However, it is not the intent of the inventors to limit the application of the invention to the details shown. Modification of the features or components of the invention can be made without deviating from the spirit of the invention and thus still remains within the scope of the claims.

What is claimed is:

1. A method for fabricating a group III-V n-type nitride structure, the method comprising:
fabricating a growth Si substrate;
depositing a group III-V n-type layer above the Si substrate using silane gas (SiH₄) as a precursor at a flow rate set to a first predetermined value corresponding to a first carrier density;
reducing the SiH4 flow rate to a second predetermined value corresponding to a second carrier density during the fabrication of the n-type layer, wherein the second carrier density is less than the first carrier density; and
forming a multi-quantum-well active region above the n-type layer;
wherein the flow rate is reduced over a predetermined period of time; and
wherein the second predetermined value is reached at a predetermined, sufficiently small distance from the interface between the n-type layer and the active region.

2. The method of claim 1, wherein the second carrier density is approximately one-tenth of the first carrier density.

3. The method of claim 2, wherein the first carrier density is approximately 1×1018 cm-3 to 1×1019 cm-3.

4. The method of claim 2, wherein the second carrier density is approximately 2×1017 cm-3 and 8×1017 cm-3.

5. The method of claim 1, wherein the predetermined period of time is approximately 1,000 seconds.

6. The method of claim 1, wherein the flow rate is reduced linearly based on a substantially constant reduction speed or non-linearly based on a varying reduction speed.

7. The method of claim 1, wherein the predetermined distance is less than or equal to 1,000 angstroms.

8. The method of claim 1, wherein the predetermined distance is greater than or equal to 100 angstroms.

9. A light-emitting device, comprising:
a group III-V n-type nitride layer;
an active region; and
a group III-V p-type nitride layer,
wherein the n-type layer is epitaxially grown by using SiH4 as a precursor prior to fabricating the active region and the p-type layer;
wherein a SiH4 flow rate during the epitaxial growth of the n-type layer is gradually reduced from a first predetermined value, which corresponds to a first carrier density, to a second predetermined value, which corresponds to a second carrier density; and
wherein the light-emitting device exhibits a reverse breakdown voltage equal to or greater than 40 volts.

10. The light-emitting device of claim 9, wherein the second carrier density is approximately one-tenth of the first carrier density.

11. The light-emitting device of claim 10, wherein the first predetermined value is approximately 2 ml/min.

12. The light-emitting device of claim 10, wherein the second predetermined value is approximately 0.2 ml/min.

13. The light-emitting device of claim 9, wherein the flow rate is reduced over a predetermined period of time.

14. The light-emitting device of claim 13, wherein the predetermined period of time is approximately 1,000 seconds.

15. The light-emitting device of claim 9, wherein the second predetermined value is reached at a predetermined, sufficiently small distance from the interface between the n-type layer and the active region.

16. The light-emitting device of claim 15, wherein the predetermined distance is less than or equal to 1,000 angstroms.

17. The light-emitting device of claim 15, wherein the predetermined distance is greater than or equal to 100 angstroms.

18. The light-emitting device of claim 9, wherein the flow rate is reduced linearly based on a substantially constant reduction speed or non-linearly based on a varying reduction speed.
